(19) United States
(12) Patent Application Publication
(10) Pub. No.: US 2019/0098797 A1
(43) Pub. Date: Mar. 28, 2019

(54) ANTI-RECIRCULATION DEVICE FOR FANS

(71) Applicant: Intel Corporation, Santa Clara, CA (US)

(72) Inventors: JAVIER AVALOS GARCIA, Zapopan (MX); CASEY R. WINKEL, Hillsboro, OR (US); ENRIQUE ANTONIO BARRETO MARTINEZ, Zapopan (MX)

(21) Appl. No.: 15/713,320

(22) Filed: Sep. 22, 2017

(51) Int. Cl. H05K 7/20; F04D 29/52

(52) U.S. Cl. CPC H05K 7/20727; F04D 29/522; H05K 7/20181; H05K 7/20145

(57) ABSTRACT

Apparatuses and systems associated with anti-recirculation devices for fan-implemented coolant systems are disclosed herein. In embodiments, an apparatus for server computing may include a housing to be affixed adjacent to a fan associated with providing a flow of air to a compute, storage or network node. The housing may be in line with the flow of air, and may have an arrangement of apertures formed in a side of the housing. The apparatus may further include a gate rotatably coupled to the housing. The gate may include a door to rotate to cover the arrangement of apertures based on a lack of air being blown by the fan to prevent a back flow of air through the fan. Other embodiments may be described and/or claimed.

### TECHNICAL FIELD

The present disclosure relates to the field of coolant systems for server computing. More particularly, the present disclosure relates to anti-recirculation devices for fan-implemented coolant systems.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Legacy computer devices and/or server computing nodes have implemented fans as a means of cooling components within the computer devices and/or server computing nodes. Improper cooling of the components may result in reduced operational capabilities of the computer devices and/or the server computing nodes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates a frontal perspective view of an example anti-recirculation device, according to various embodiments.

FIG. 2 illustrates a rear perspective view of the example anti-recirculation device of FIG. 1, according to various embodiments.

FIG. 3 illustrates a perspective view of an example housing, according to various embodiments.

FIG. 4 illustrates a perspective view of an example gate, according to various embodiments.

FIG. 5 illustrates an example fan arrangement, according to various embodiments.

FIG. 6 illustrates a cross-sectional view of an example anti-recirculation device in a first state, according to various embodiments.

FIG. 7 illustrates a frontal view of the example anti-recirculation device of FIG. 6 in the first state, according to various embodiments.

FIG. 8 illustrates a cross-sectional view of the example anti-recirculation device of FIG. 6 in a second state, according to various embodiments.

FIG. 9 illustrates a rear perspective view of the example anti-recirculation device of FIG. 6 in the second state, according to various embodiments.

FIG. 10 illustrates an example computing device that may employ the apparatuses and/or methods described herein.

FIG. 11 illustrates an example computing node arrangement, according to various embodiments.

### DETAILED DESCRIPTION

Apparatuses and systems associated with anti-recirculation devices for fan-implemented coolant systems are disclosed herein. In embodiments, an apparatus for server computing may include a housing to be affixed adjacent to a fan associated with providing a flow of air to a compute, storage or network node. The housing may be in line with the flow of air, and may have an arrangement of apertures formed in a side of the housing. The apparatus may further include a gate rotatably coupled to the housing. The gate may include a door to rotate to cover the arrangement of apertures based on a lack of air being blown by the fan to prevent a back flow of air through the fan. Other embodiments may be described and/or claimed.

The apparatus and system disclosed herein may address back flow issues that may be presented by the fan associated with providing the flow of air to the compute, storage or network node. In particular, while fans are a useful way of cooling components within the compute, storage or network nodes, a back flow of air across the components may result when a fan stops blowing air, possibly due to fan failure. This back flow of air may cause insufficient cooling of the components, which may result in failure of, and/or damage to, the components.

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

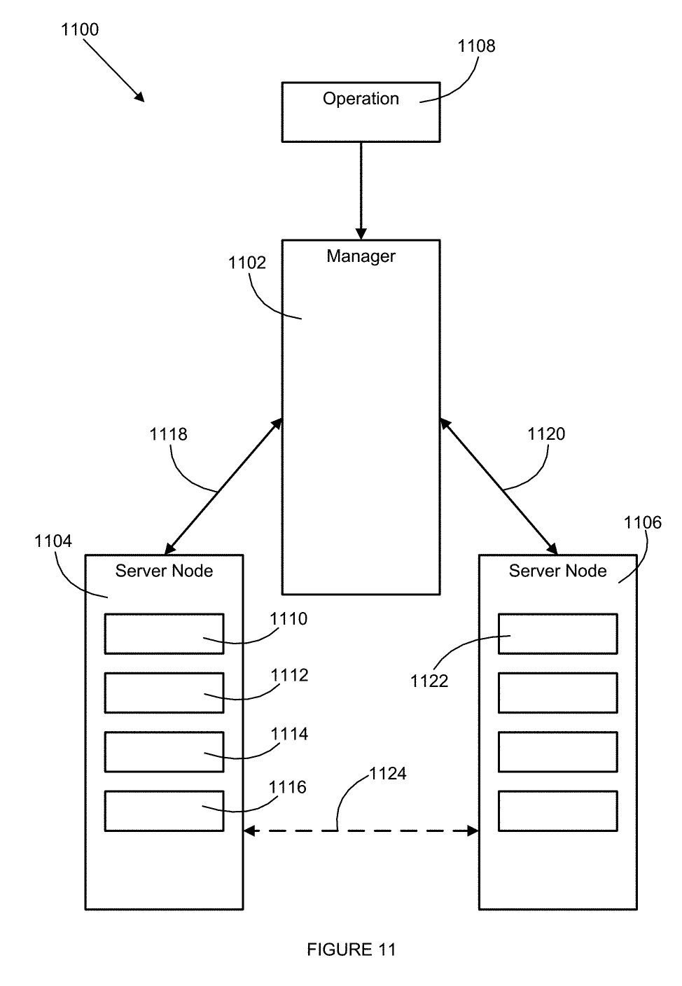

As used herein, the term “server computing node” may refer to a server node described in relation to FIG. 11, such as the server node 1104 and/or the server node 1106. The server computing node may refer to node in a pooled-by-node arrangement, where the server computing node may refer to a compute node, a storage node, or a network node. In other embodiments, server computing node may refer to a node that is in a pooled-by-drawer arrangement or a heterogeneous arrangement.

Directional terms, such as “front side,” “backside,” and “top side,” are used throughout this disclosure. It is to be understood that the directional terms are not to limit directions of the elements, but to help define a relationship between the elements. Further, the directional terms may be referred to without the directional indicator throughout this disclosure.

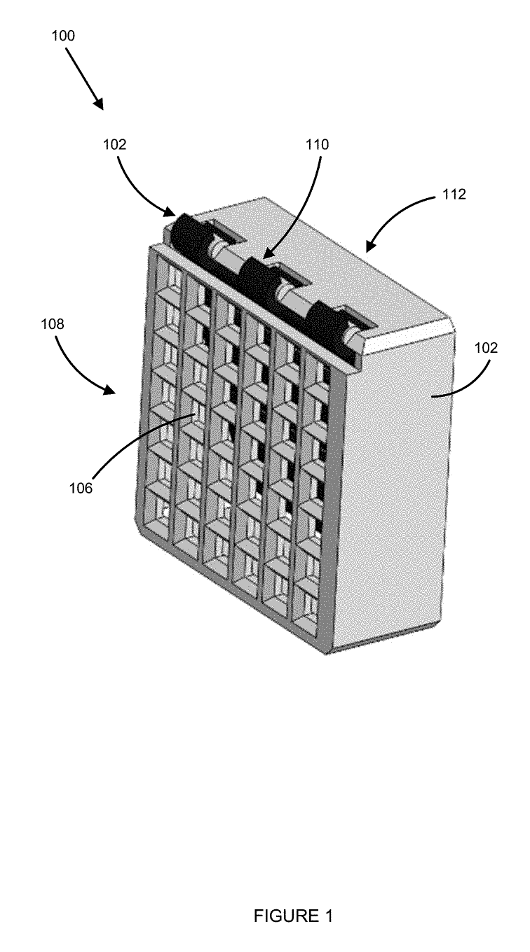

FIG. 1 illustrates a frontal perspective view of an example anti-recirculation device 100, according to various embodiments. The anti-recirculation device 100 may include a housing 102 and a gate 104. The housing 102 and the gate 104 may be formed of a rigid material, such as hard plastic, hard rubber, metal, glass, other rigid materials, or some combination thereof. In some embodiments, the housing 102 and the gate 104 may both be plastic and may be formed by an injection molding process. In other embodiments, the housing 102 may be formed of a different material from the gate 104.

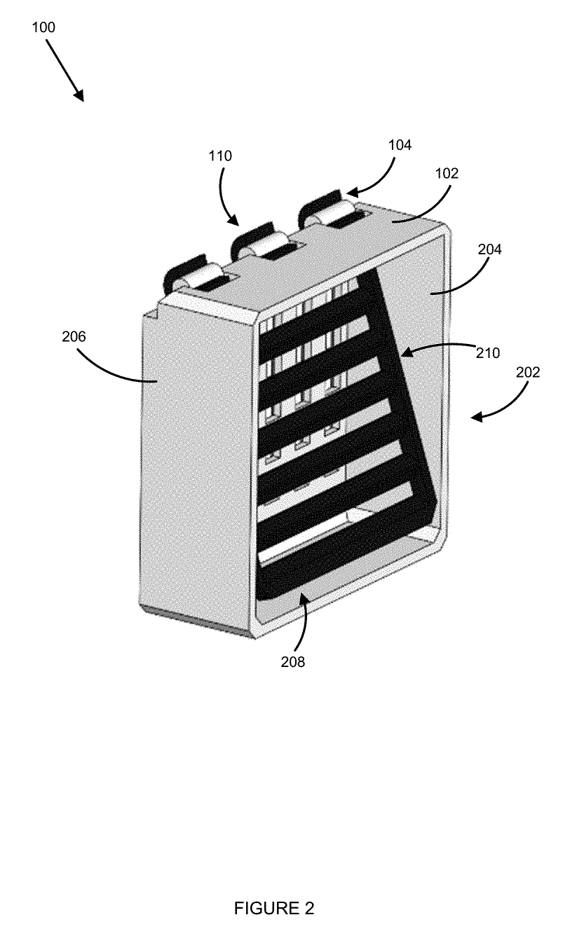

The housing 102 may have a front side 108 and a backside 202 (see FIG. 2), wherein the front side 108 is located on an opposite side of the housing from the backside 202. The housing 102 may have an arrangement of apertures 106 formed in the front side 108 of the housing 102. The arrangement of apertures 106 may extend for an entirety of the front side 108. In the illustrated embodiment, the arrangement of apertures 106 is a grid of apertures. In other embodiments, the arrangement of apertures 106 may be in any other arrangement capable of satisfying the features described throughout this disclosure, including a series of apertures that extend horizontally across the front side 108, a series of apertures that extend vertically across the front side 108, and/or a series of apertures that extend diagonally across the front side 108.

The housing 102 may be shaped to mate with an inlet and/or an outlet of a fan to which the housing 102 is to be affixed adjacent to. In the illustrated embodiment, the housing 102 may be rectangular-shaped and may mate with a rectangular inlet and/or a rectangular outlet of a fan. In other embodiments, the housing 102 may have a different shape based on the shape of the inlet and/or the outlet of the fan. For example, the housing 102 may be circular in embodiments where the inlet and/or the outlet of the fan is circular. Further, in other embodiments, the housing 102 may be a different shape than the inlet and/or the outlet of the fan to which the housing 102 is to be affixed adjacent to.

Further, the housing 102 may be sized to be larger than or equal to a size of an inlet and/or an outlet of a fan to which the housing 102 is to be affixed adjacent to. In particular, the housing 102 may be sized such that the front side 108 of the housing 102 and/or the backside 202 of the housing 102 may encompass the inlet and/or the outlet of the fan. Accordingly, the height of the housing 102 may be greater than or equal to the height of the fan, and the width of the housing 102 may be greater than or equal to the width of the fan. When the housing 102 is affixed adjacent to the fan, the air being drawn in or blown out through the fan may pass through the housing 102 based on the front side 108 and/or the backside 202 encompassing the inlet and/or the outlet of the fan.

The housing 102 may further be designed to have a depth (measured from the front side 108 to the backside 202 of the housing 102) based on an application in which the anti-recirculation device 100 is to be implemented. In particular, a position in which the anti-recirculation device 100 is to be affixed may provide for a limited depth of the housing 102. For example, in some embodiments, the housing 102 may have a depth of less than three-quarters of an inch (1.905 centimeters). In other embodiments, the depth of the housing 102 may be greater than three-quarters of an inch.

The gate 104 may include a coupling member 110 to couple to a portion of the housing 102. In particular, the coupling member 110 may rotatably couple the gate 104 to the portion of the housing 102, wherein the gate 104 may rotate about the portion of the housing 102. The portion of the housing 102 may be located in a top side 112 of the housing 102. In some embodiments, the portion of the housing 102 may rotate to provide the rotatable coupling of the coupling member 110. In other embodiments, the coupling member 110 may provide the rotation for the rotatable coupling of the coupling member 110, such as in embodiments where the coupling member 110 includes a hinge assembly or there is little friction between the coupling member 110 and the portion of the housing 102 when the coupling member 110 is coupled to the portion of the housing 102.

The coupling member 110 may form a hinge with the portion of the housing 102. The portion of the housing 102 may be located directly above the arrangement of apertures 106 or may be offset by a certain distance from directly above the arrangement of apertures 106. In particular, the portion of the housing 102 may be designed such that as the gate 104 rotates to cover the arrangement of apertures 106 (described further throughout this disclosure) the door 208 (see FIG. 2) extends parallel to the front side 108. In the illustrated embodiment, the portion of the housing 102 includes three circular members formed in the housing 102. Further, the coupling member 110 includes three clip members that clip onto the three circular members and partially encircle the three circular members to rotatably couple the gate 104 about the three circular members. In some embodiments, the three circular members may include a circular attachment mechanism (such as a rod and/or a dowel) that couples the three circular members to the rest of the housing 102 and allows the three circular members to freely rotate about the circular attachment mechanism. In other embodiments, the portion of the housing 102 may include more or less than circular members than the three circular members. Further, in other embodiments, the circular members may be different shape that circular, including, but not limited to, hexagonal, octagonal, or other polygon shapes.

In other embodiments, the coupling member 110 of the gate 104 may include a hinge assembly. A first leaf of the hinge assembly may be connected to the door 208 of the gate 104 and a second leaf of the hinge assembly may be connected to the portion of the housing 102. In some embodiments, the connections between the first leaf and the door 208, and the second leaf and the portion of the housing 102 may include connecting the elements via epoxy, fasteners, or some combination thereof.

FIG. 2 illustrates a rear perspective view of the example anti-recirculation device 100 of FIG. 1, according to various embodiments. The housing 102 may include a backside 202 located on an opposite side of the housing 102 from the front side 108 (FIG. 1). The housing 102 may have an aperture 204 formed in the backside 202. The aperture 204 may extend for an entirety of the backside 202. In other embodiments, housing 102 may have one or more apertures formed in the backside 202, or may include an arrangement of apertures (such as the arrangement of apertures 106 (FIG. 1)) formed in the backside 202.

The housing 102 may further include one or more sidewalls 206 that extend between the front side 108 and the backside 202 of the housing 102. The sidewalls 206 may encircle the space located between the front side 108 and the backside 202 of the housing 102. In the illustrated embodiment, the housing 102 includes four sidewalls 206 that encircle the space between the front side 108 and the backside 202 of the housing 102. In other embodiments, there may be more or less sidewalls 206 and/or the sidewalls 206 may be straight or curved.

The gate 104 may further include a door 208. The door 208 may be connected to the coupling member 110 and may rotate about the portion of the housing 102 to which the coupling member 110 is rotatably coupled. The door 208 may include a plurality of slats 210 with apertures located between each of the slats. In the illustrated embodiment, the plurality of slats 210 extend in a horizontal direction for substantially an entirety of the door 208. In other embodiments, the plurality of slats 210 may extend in other directions, including a vertical direction and/or a diagonal direction. Further, in some embodiments, a first portion of the plurality of slats may extend in a first direction and a second portion of the plurality of slats may extend in a second direction that is different from the first direction. Further, in some embodiments, the plurality of slots 210 may extend for a portion of the entirety of the door 208, and/or a first portion of the plurality of slots 210 may extend for a first portion of the entirety of the door 208 and a second portion of the plurality of slots 210 may extend for a second portion of the entirety of the door 208 that is different from the first portion.

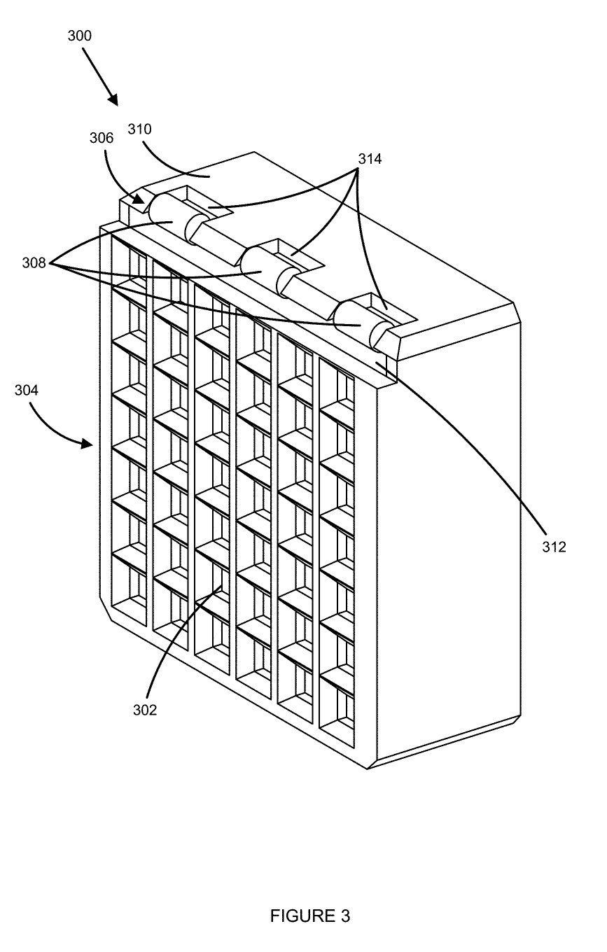

FIG. 3 illustrates a perspective view of an example housing 300, according to various embodiments. The housing 300 may include one or more of the features of the housing 102 (FIG. 1) and/or may be implemented in the anti-recirculation device 100 (FIG. 1). In particular, the housing 300 may have an arrangement of apertures 302 formed in a front side 304 of the housing 300, wherein the arrangement of apertures 302 may include one or more of the features of the arrangement of apertures 106 (FIG. 1). Further, the housing 300 may include a backside (obscured due to viewpoint) located on an opposite side of the housing 300 from the front side 304, wherein the backside may include one or more of the features of the backside 202 (FIG. 2).

The housing 300 may further include a portion 306 of the housing 300 to which a coupling member (such as the coupling member 110 (FIG. 1)) of a gate (such as the gate 104 (FIG. 1)) may rotatably couple. The portion 306 may include one or more circular members 308 to which the coupling member may rotatably couple. The circular members 308 may be formed in a top side 310 of the housing 300 and may be located above the arrangement of apertures 302. In particular, the circular members 308 may be located directly above the arrangement of apertures 302 or may be offset toward the backside of the housing 300 from the arrangement of apertures 302.

In some embodiments, the circular members 308 may be formed of the same piece of material as the housing 300 and may be rigidly affixed to the top side 310 of the housing 300. In these embodiments, the coupling member of the gate may rotatably couple to the circular members 308 with little friction between the coupling member and the circular members 308 such that coupling member may rotate about the circular members 308 while the circular members 308 do not rotate. In some of these embodiments, a friction-reducing element or material may be located between, or applied to, the circular members 308 and the coupling member, such as lubrication, bearings, a low-friction applicate, or some combination thereof.

In other embodiments, the circular members 308 may be formed of different pieces of material from the housing 300 and may rotate relative to the rest of the housing 300. In these embodiments, each of the circular members 308 may be coupled to the rest of the housing via one or more rods, dowels, or other member (collectively referred to as “the rod”). The rod may be coupled to, or extend through, a center of each of the circular members 308 and the circular members 308 may rotate about the rod. In these embodiments, the coupling member may be rigidly coupled to the circular members 308 and the rotation of the circular members 308 may provide the rotation for the rotatable coupling of the coupling member to the circular members 308. Further, in some of these embodiments, the circular members 308 may be other shapes other than circular, including, but not limited to, hexagonal, octagonal, or other polygon shapes.

The housing 300 may further have an aperture 312 located between the top side 310 of the housing 300 and the arrangement of apertures 302. Further, the housing 300 may have one or more apertures 314 formed in the top side 310 adjacent to the portion 306 of the housing 300. The aperture 312 and the apertures 314 may provide for the rotatable coupling of the coupling member to the portion 306 of the housing 300. In particular, a portion or portions of the coupling member may extend through the aperture 312 and/or the apertures 314 when the coupling member is rotatably coupled to the portion 306 of the housing 300 and/or depending on a position of the gate. Further, when the gate is in a position where the door of the gate is covering the arrangement of apertures 302, the gate may further cover the aperture 312 and/or the apertures 314, thereby preventing airflow through the aperture 312 and/or the apertures 314.

In some embodiments, the aperture 312, the apertures 314, or both may be omitted. In some of these embodiments, the coupling member of the gate may rotatably couple to an inside of the housing 300. For example, the coupling member may include a hinge assembly and one of the leafs of the hinge assembly may be coupled the inside of the housing 300 with the hinge assembly providing the rotatable coupling of the coupling member.

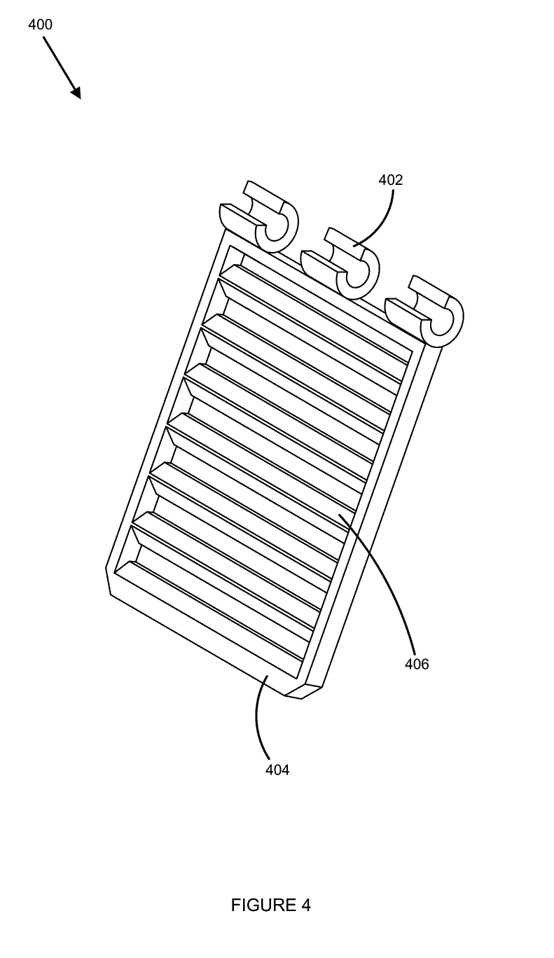

FIG. 4 illustrates a perspective view of an example gate 400, according to various embodiments. In particular, a backside of the gate 400 is illustrated, where the front side of the gate 400 faces an arrangement of apertures (such as the arrangement of apertures 106 (FIG. 1) and/or the arrangement apertures 302 (FIG. 3)) of a housing (such as the housing 102 (FIG. 1) and/or the housing 300 (FIG. 3)) when the gate 400 is coupled to the housing. The gate 400 may include one or more of the features of the gate 104 (FIG. 1) and/or may be implemented in the anti-recirculation device 100 (FIG. 1). In particular, the gate 400 may include a coupling member 402, which may include one or more of the features of the coupling member 110 (FIG. 1). Further, the gate 400 may include a door 404, which may include one or more of the features of the door 208 (FIG. 2).

The door 404 may be connected to the coupling member 402. In some embodiments, the door 404 and the coupling member 402 may be formed of a same piece of material. In other embodiments, the door 404 and the coupling member 402 may be formed of different pieces of material and may be coupled to each other via epoxy, fasteners, or some combination thereof. For example, in embodiments where the coupling member 402 includes a hinge assembly, the door 404 may be connected to a leaf of the hinge assembly via epoxy, fasteners, or some combination thereof.

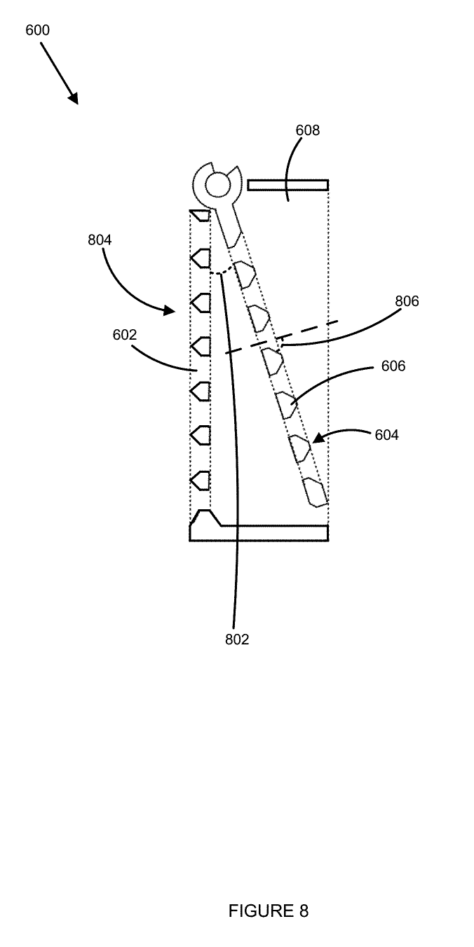

The door 404 may include a plurality of slats 406. The plurality of slats 406 may include one or more of the features of the plurality of slats 210 (FIG. 2). Each slat, of the plurality of slats 210, may be tapered toward the backside of the gate. In particular, when the gate 400 is coupled to the housing, each slat may be tapered toward the side of the gate 400 opposite to the front side of the housing. An amount of the taper of each slat may be selected to limit impedance of air passing through the plurality of slats 210 (described further in relation to FIG. 8). For example, the amount of taper of each slat may be based on an angle of the gate 400 to the front side of the housing when the door 404 is rotated away from the front side of the housing. In some embodiments, an angle of the taper of each slat may be equal to the angle of the gate 400 to the front side of the housing when the door 404 is rotated away from the front side. In other embodiments, the angle of the taper of each slat may be greater than the angle of the gate 400 to the front side of the housing when the door 404 is rotated away from the front side.

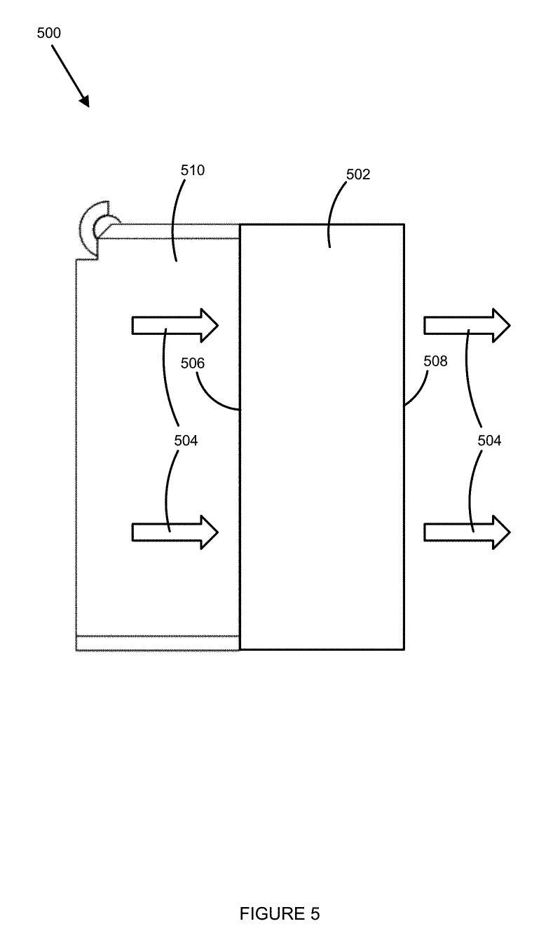

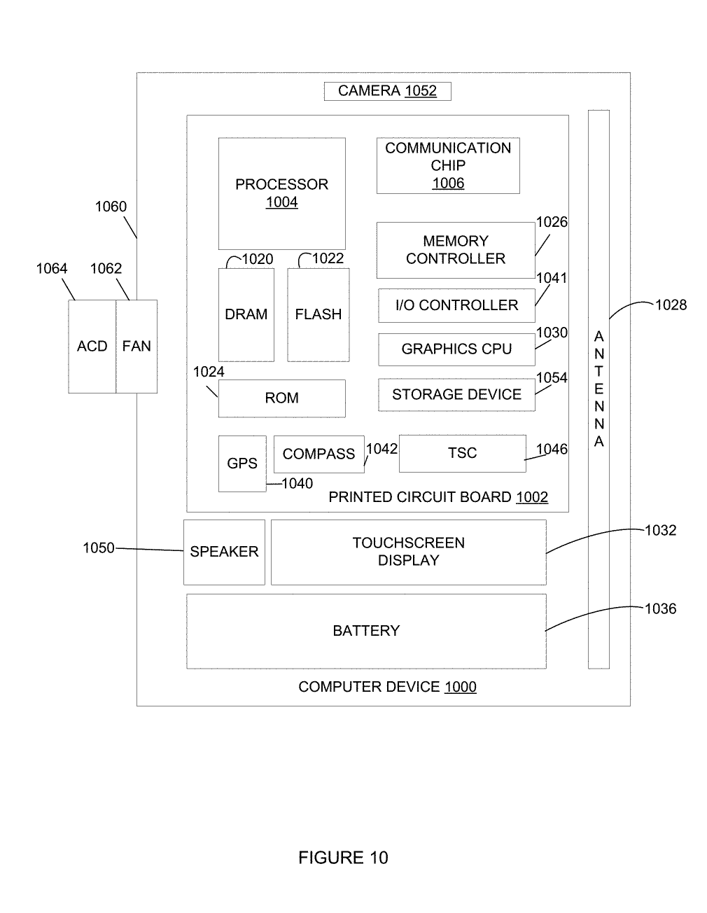

FIG. 5 illustrates an example fan arrangement 500, according to various embodiments. The fan arrangement 500 may include a fan 502. The fan 502 may be any fan that may be utilized for cooling of a computer device (such as the computer device 1000 (FIG. 10)), a server computing node, a manager (such as the manager 1102 (FIG. 11)), a server node (such as the server node 1104 (FIG. 11) and/or the server node 1106 (FIG. 11)), a portion of any of the previously listed components, or some combination thereof. The fan 502 may draw air in through an inlet 506 of the fan 502 and blow air out of an outlet 508 of the fan 502 (as indicated by arrows 504) when the fan 502 is operating. In some embodiments, the inlet 506 may be located on an opposite side of the fan 502 from the outlet 508. The side of the fan 502 corresponding to the inlet 506 may be referred to as the “upstream side” of the fan 502 and the side of the fan 502 corresponding to the outlet 508 may be referred to as the “downstream side” of the fan 502.

The fan arrangement 500 may further include an anti-recirculation device 510. The anti-recirculation device 510 may include one or more of the features of the anti-recirculation device 100 (FIG. 1). In particular, the anti-recirculation device 510 may include a housing, which may include one or more of the features of the housing 102 (FIG. 1) and/or the housing 300 (FIG. 3). Further, the anti-recirculation device 510 may include a gate, which may include one or more of the features of the gate 104 (FIG. 1) and/or the gate 400 (FIG. 4).

The anti-recirculation device 510 may be affixed adjacent to the fan 502. In particular, the anti-recirculation device 510 may be affixed directly to the fan 502 or to a mounting structure that affixes the anti-recirculation device 510 adjacent to the fan 502. The mounting structure may be part of a case (such as the case 1060 (FIG. 10)) of a computer device and/or a server computing node associated with the fan 502 or may be coupled to the case. In some embodiments, the anti-recirculation device 510 may be affixed at an upstream side of the fan 502. In other embodiments, the anti-recirculation device 510 may be affixed at a downstream side of the fan 502.

The anti-recirculation device 510 may generate an air-tight, or a substantially air-tight (where a limited amount of air flow may flow between the fan 502 and the mounting structure), seal between the air-recirculation device 510 and the fan 502. In some embodiments, an epoxy and/or adhesive may be located between the anti-recirculation device 510 and the fan 502 (and/or the mounting structure) to generate the air-tight, or the substantially air-tight, seal. Further, in some embodiments, a gasket may be located between the anti-recirculation device 510 and the fan 502 (and/or the mounting structure) to generate the air-tight, or the substantially air-tight, seal.

In embodiments where the anti-recirculation device 510 is affixed at an upstream side of the fan 502, a front side (such as the front side 108 (FIG. 1) and/or the front side 304 (FIG. 3)) of the anti-recirculation device 510 may be located opposite to the fan 502. For example, an arrangement of apertures (such as the arrangement of apertures 106 (FIG. 1)) of the anti-recirculation device 510 may be located on an opposite side of the anti-recirculation device 510 from the fan 502. Further, a backside (such as the backside 202 (FIG. 2)) of the anti-recirculation device 510 may abut the fan 502 and/or the mounting structure. The backside of the anti-recirculation device 510 may generate, or facilitate, the air-tight, or the substantially air-tight, seal with the fan 502. When the fan 502 is not blowing air, the gate of the anti-recirculation device 510 may be against the arrangement of apertures of the anti-recirculation device 510 and may cover the arrangement of apertures, thereby preventing airflow through the arrangement of apertures. When the fan 502 is blowing air, a pressure difference may be generated between the inside of the anti-recirculation device 510 and surroundings of the anti-recirculation device 510, which may rotate the gate away from the arrangement of apertures, uncovering the arrangement of apertures, and allowing airflow through the arrangement of apertures. In particular, when the fan 502 is blowing air, suction may be generated within the anti-recirculation device 510, which may draw the gate away from the arrangement of apertures. As the fan continues to blow air, the gate may be maintained away from the arrangement of apertures by force generated on the gate via airflow through the arrangement of apertures.

In embodiments where the anti-recirculation device 510 is affixed at a downstream side of the fan 502, the front side of the anti-recirculation device 510 may abut the fan 502 and/or the mounting structure. For example, the arrangement of apertures may be located on a side of the anti-recirculation device 510 closest to the fan. The front side of the anti-recirculation device 510 may generate the air-tight, or the substantially air-tight, seal with the fan 502. The backside of the anti-recirculation device 510 may be located on an opposite side of the anti-recirculation device 510 from the fan 502. When the fan 502 is not blowing air, the gate of the anti-recirculation device 510 may be against the arrangement of apertures of the anti-recirculation device 510 and may cover the arrangement of apertures, thereby preventing airflow through the arrangement of apertures. When the fan 502 is blowing air, the air blown by the fan 502 may apply force to the gate, causing the gate to rotate away from the arrangement of apertures, allowing airflow through the arrangement of apertures.

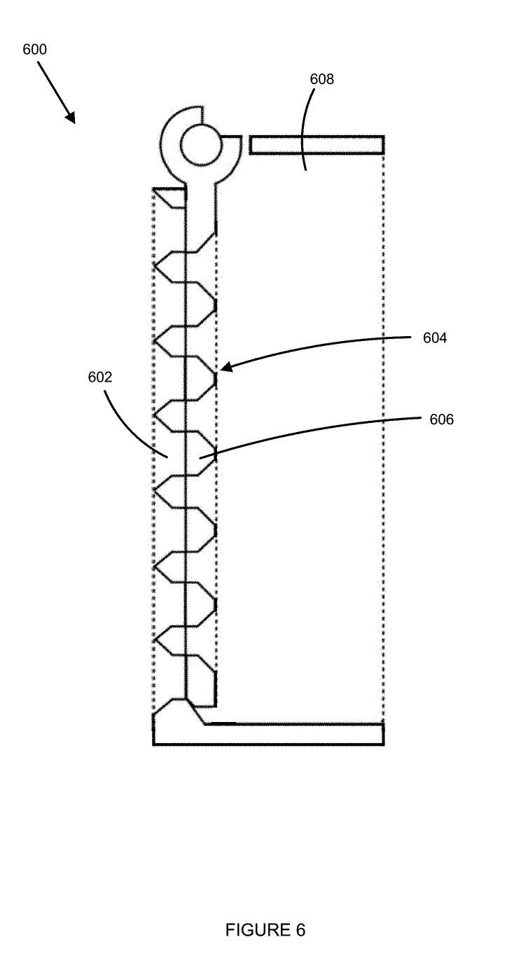

FIG. 6 illustrates a cross-sectional view of an example anti-recirculation device 600 in a first state, according to various embodiments. Dotted lines in FIG. 6 are utilized to illustrate structure of the anti-recirculation device 600 that may be set back from the cross-section for clarity. In particular, the dotted lines indicates sides of arrangement of apertures 602, sides of gate 604, and backside of the anti-recirculation device 600.

The anti-recirculation device 600 may include one or more of the features of the anti-recirculation device 100 (FIG. 1) and/or the anti-recirculation device 510 (FIG. 5). In particular, the anti-recirculation device 600 may include a housing 608 having an arrangement of apertures 602 and a gate 604. The housing 608 may include one or more of the features of the housing 102 (FIG. 1) and/or the housing 300 (FIG. 3). The arrangement of apertures 602 may include one or more of the features of the arrangement of apertures 106 (FIG. 1) and/or the arrangement of apertures 302 (FIG. 3). The gate 604 may include one or more of the features of the gate 104 (FIG. 1) and/or the gate 400 (FIG. 4).

In the first state, the gate 604 may be rotated such that a door 606 (as illustrated as a plurality of slats due to the cross-sectional view) of the gate 604 covers the arrangement of apertures 602. In particular, the plurality of slats of the door 606 may abut the apertures of the arrangement of apertures 602 and cover the arrangement of apertures 602, thereby preventing airflow through the arrangement of apertures 602. The anti-recirculation device 600 may be in the first state based on a lack of air being blown by a fan (such as the 502 (FIG. 5)) to which the anti-recirculation device 600 is affixed adjacent to. The anti-recirculation device 600 may prevent a back flow of air through the fan when the anti-recirculation device 600 is in the first state.

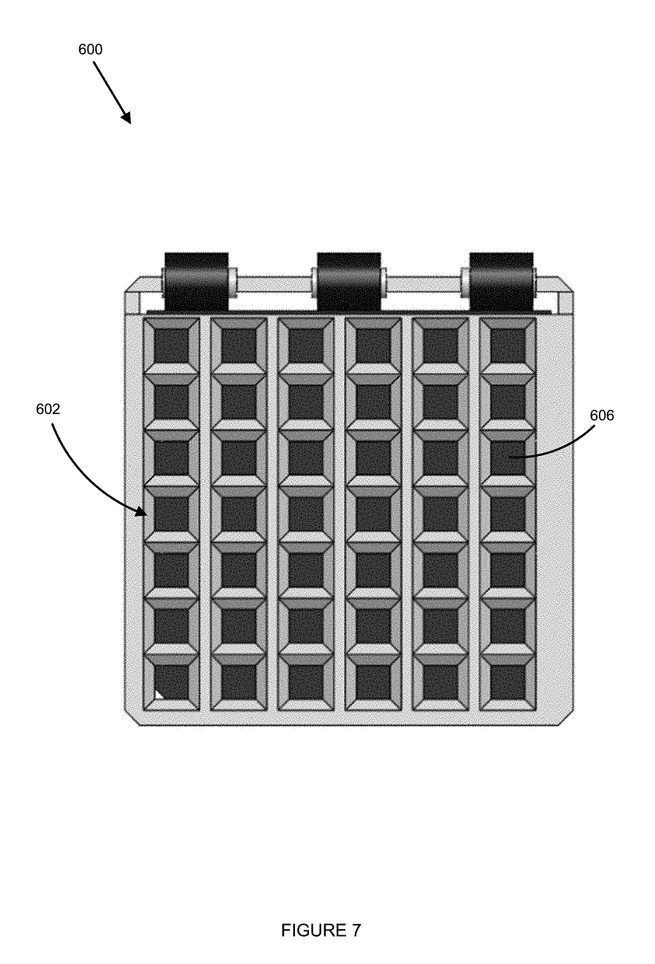

FIG. 7 illustrates a frontal view of the example anti-recirculation device 600 of FIG. 6 in the first state, according to various embodiments. When in the first state, the door 606 may cover the arrangement of apertures 602, as illustrated. The door 606 may prevent airflow through the arrangement of apertures 602 when the door 606 is covering the arrangement of apertures 602.

FIG. 8 illustrates a cross-sectional view of the example anti-recirculation device 600 of FIG. 6 in a second state, according to various embodiments. Dotted lines in FIG. 8 are utilized to illustrate structure of the anti-recirculation device 600 that may be set back from the cross-section for clarity. In particular, the dotted lines indicates sides of arrangement of apertures 602, sides of gate 604, and backside of the anti-recirculation device 600.

In the second state, the gate 604 may be rotated such that the door 606 is rotated away from the front side of the housing 608. Further, the door 606 may uncover the arrangement of apertures 602 when the anti-recirculation device 600 is in the second state, which may allow air to pass through the arrangement of apertures 602. The door 606 may be designed to remain inside of the housing 608 when the rotated away from the front side of the housing 608, such as by providing a physical stop to prevent the door 606 from rotating outside of the housing 608. In other embodiments, an amount of rotation of the door 606 may not be limited.

The air may pass through the plurality of slats of the door 606 when the anti-recirculation device 600 is in a second state, which may limit the impedance of the air passing through the arrangement of apertures 602 caused by the door 606. In some embodiments, each slat, of the plurality of slats, may be tapered toward a side of the gate 604 located away from the arrangement of apertures 602. The tapering may further limit the impedance of the air caused by the door 606. In some embodiments, an amount of taper of each slat may be based on an angle 802 between a front side 804 of the housing 608 and the gate 604 when the anti-recirculation device 600 is in the second state. An angle 806 of the taper of each slat may be equal to the angle 802 between the front side 804 of the housing 608 and the gate 604. In some embodiments, the angle 806 of the taper of each slat may be greater than the angle 802 between the front side 804 of the housing 608 and the gate 604.

The anti-recirculation device 600 may be in the second state based on air being blown by the fan. In particular, the anti-recirculation device 600 may transition from the first state to the second state in response to a pressure difference being generated between the inside of the anti-recirculation device 600 and surroundings of the anti-recirculation device 600 caused by the fan blowing air. The anti-recirculation device 600 may remain in the second state based on air being drawn in through the arrangement of apertures 602, caused by the fan blowing air, applying a force to the door 606 that maintains the door 606 rotated away from the front side 804 of the housing 608. The anti-recirculation device 600 may transition from the second state to the first state in response to the fan stopping blowing air. In particular, the weight of the door 606 may cause the gate 604 to rotate to have the door 606 covering the arrangement of apertures 602 in the absence of the pressure difference and the force being applied to the door 606 via the air being drawn in through the arrangement of apertures 602. The anti-recirculation device 600 may remain in the second state until the fan begins blowing air.

In accordance with the description of the transitions between the first state and the second state described above, the anti-recirculation device 600 may be a passive device. In particular, the anti-recirculation device 600 may not rely on an actuator (such as a motor) to cause rotation of the gate 604. Accordingly, the anti-recirculation device 600 may eliminate a possible point of operation failure by not relying on an actuator, which may fail, to cause rotation of the gate 604.

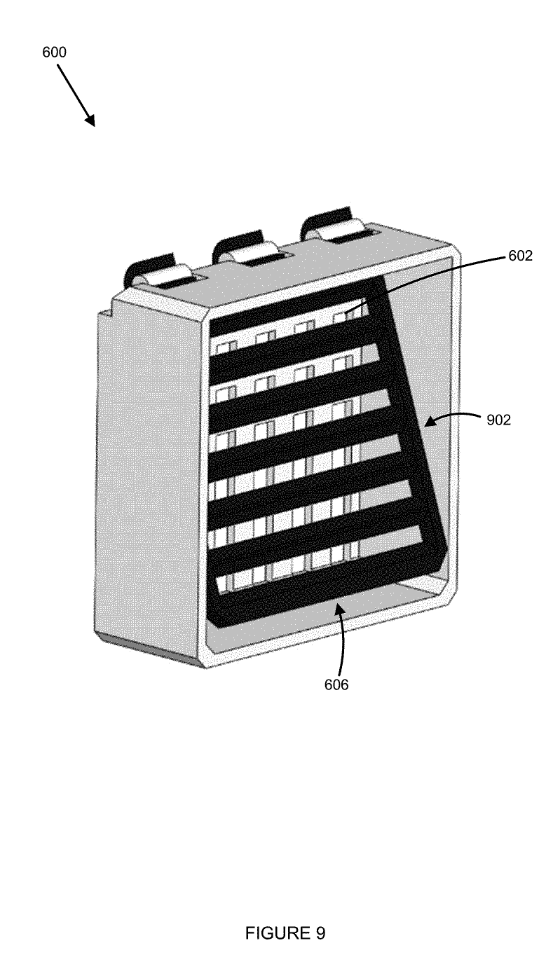

FIG. 9 illustrates a rear perspective view of the example anti-recirculation device 600 of FIG. 6 in the second state, according to various embodiments. As illustrated, the door 606 may be rotated away from the arrangement of apertures 602 when the anti-recirculation device 600 is in the second state. Further, the door 606 may uncover the arrangement of apertures 602, allowing air to flow through the arrangement of apertures 602 and through the plurality of slats 902 of the door 606 in the second state.

FIG. 10 illustrates an example computer device 1000 that may employ the apparatuses and/or methods described herein (e.g., the anti-recirculation device 100, the anti-recirculation device 510, and/or the anti-recirculation device 600), in accordance with various embodiments. As shown, computer device 1000 may include a number of components, such as one or more processor(s) 1004 (one shown) and at least one communication chip 1006. In various embodiments, the one or more processor(s) 1004 each may include one or more processor cores. In various embodiments, the at least one communication chip 1006 may be physically and electrically coupled to the one or more processor(s) 1004. In further implementations, the communication chip 1006 may be part of the one or more processor(s) 1004. In various embodiments, computer device 1000 may include printed circuit board (PCB) 1002. For these embodiments, the one or more processor(s) 1004 and communication chip 1006 may be disposed thereon. In alternate embodiments, the various components may be coupled without the employment of PCB 1002.

Depending on its applications, computer device 1000 may include other components that may or may not be physically and electrically coupled to the PCB 1002. These other components include, but are not limited to, memory controller 1026, volatile memory (e.g., dynamic random access memory (DRAM) 1020), non-volatile memory such as read only memory (ROM) 1024, flash memory 1022, storage device 1054 (e.g., a hard-disk drive (HDD)), an I/O controller 1041, a digital signal processor (not shown), a crypto processor (not shown), a graphics processor 1030, one or more antenna 1028, a display (not shown), a touch screen display 1032, a touch screen controller 1046, a battery 1036, an audio codec (not shown), a video codec (not shown), a global positioning system (GPS) device 1040, a compass 1042, an accelerometer (not shown), a gyroscope (not shown), a speaker 1050, a camera 1052, and a mass storage device (such as hard disk drive, a solid state drive, compact disk (CD), digital versatile disk (DVD)) (not shown), and so forth.

In some embodiments, the one or more processor(s) 1004, flash memory 1022, and/or storage device 1054 may include associated firmware (not shown) storing programming instructions configured to enable computer device 1000, in response to execution of the programming instructions by one or more processor(s) 1004, to provide an operating system and/or one or more applications. In various embodiments, the operating system and/or the one or more applications may additionally or alternatively be implemented using hardware separate from the one or more processor(s) 1004, flash memory 1022, or storage device 1054.

The communication chips 1006 may enable wired and/or wireless communications for the transfer of data to and from the computer device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to IEEE 802.20, Long Term Evolution (LTE), LTE Advanced (LTE-A), General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The computer device 1000 may include a plurality of communication chips 1006. For instance, a first communication chip 1006 may be dedicated to shorter range wireless communications such as Wi-Fi and Bluetooth, and a second communication chip 1006 may be dedicated to longer range wireless communications such as GPS, EDGE, GPRS, CDMA, WiMAX, LTE, Ev-DO, and others.

The computer device 1000 may further include a case 1060. The case 1060 may enclose and/or house one or more of the components of the computer device 1000 and may facilitate protection of the components from potential damage. The case 1060 may be a desktop computer case, a laptop computer case, a server case, a server drawer case, or any other case that may be utilized for a computer device 1000 as known by one having ordinary skill in the art.

The computer device 1000 may further include one or more fans 1062. The fans 1062 may be coupled to the case 1060 and may provide a flow of air to the components enclosed or housed by the case 1060 of the computer device 1000. In particular, the fans 1062 may blow air into the case 1060 or draw air out of the case 1060 to cool the components enclosed or housed by the case 1060.

The computer device 1000 may further include one or more anti-recirculation devices 1064. The anti-recirculation devices 1064 may include one or more of the features of the anti-recirculation device 100 (FIG. 1), the anti-recirculation device 510 (FIG. 5), and/or the anti-recirculation device 600 (FIG. 6). Each of the anti-recirculation devices 1064 may be affixed adjacent to corresponding ones of the fans 1062 for a one-to-one ratio of anti-recirculation devices 1064 to fans 1062. Each anti-recirculation device 1064 and corresponding fan 1062 may form a fan arrangement, which may include one or more of the features of the fan arrangement 500 (FIG. 5).

In various implementations, the computer device 1000 may be a laptop, a netbook, a notebook, an ultrabook, a smartphone, a computer tablet, a personal digital assistant (PDA), an ultra-mobile PC, a mobile phone, a desktop computer, a server, a printer, a scanner, a monitor, a set-top box, an entertainment control unit (e.g., a gaming console or automotive entertainment unit), a digital camera, an appliance, a portable music player, a digital video recorder, a manager (such as the manager 1102 (FIG. 11)), or a server node (such as the server node 1104 (FIG. 11) and/or the server node 1106 (FIG. 11)). In further implementations, the computer device 1000 may be any other electronic device that processes data.

FIG. 11 illustrates an example computing node arrangement 1100, according to various embodiments. The computing node 1100 may include a manager 1102 and one or more server nodes, such as server node 1104 and server node 1106. The one or more server nodes may be communicatively coupled to the manager 1102, thereby allowing communication between the between the server nodes and the manager 1102 (as illustrated by communication link 1118 and communication link 1120). The manager 1102 and each of the server nodes may be referred to as a computing node. The following description refers to the server node 1104 and the server node 1106, however, it is to be understood that any of the server nodes within the one or more server nodes may include one or more of the feature of the server node 1104, the server node 1106, or some combination thereof.

The manager 1102 may receive an operation 1108 to be performed. The manager 1102 may include one or more communication chips, such as the communication chips 2206 (FIG. 22). The manager 1102 may wirelessly receive or wiredly receive the operation 1108 from a requesting device via the communication chips. The manager 1102 may separate the operation 1108 into one or more discrete operations and/or data groupings for storage.

The server node 1104 may be a server rack. The server node 1104 may include one or more drawers (which may also be referred to as sleds), such as drawer 1110, drawer 1112, drawer 1114, and drawer 1116. The server node 1104 may be arranged in a pooled-by-node arrangement. In the pooled-by-node arrangement, each of the drawers of the server node 1104 may include one or more components to provide a certain resource type. The resource types may include a network resource type, a storage resource type, and a compute resource type. For example, the drawer 1110, the drawer 1112, the drawer 1114, and the drawer 1116 may each include components to provide a compute resource type.

In other embodiments, the server node 1104 may be arranged in a pooled-by-drawer arrangement. In the pooled-by-drawer arrangement, each of the drawers may include one or more components to provide a certain resource type, but each of the drawers may include components to provide a different resource type than provided by the components within another one of the drawers of the server node 1104. For example, the drawer 1110 may include components to provide a network resource type, the drawer 1112 may include components to provide a storage resource type, and the drawer 1114 may include components to provide a compute resource type.

Further, in other embodiments, the server node 1104 may be arranged in a heterogeneous arrangement. In the heterogeneous arrangement, each of the drawers may include components to provide multiple resource types. Each of the drawers may include components to provide all the resource types or some portion of the resource types. For example, the drawer 1110 may include components to provide a network resource type, components to provide a storage resource type, and components to provide a compute resource type.

In some embodiments, the server node 1104 may be arranged in a combination of the pooled-by-drawer arrangement and the heterogeneous arrangement. In these embodiments, a first portion of the drawers of the server node 1104 may be arranged in the pooled-by-drawer arrangement and a second portion of the drawers may be arranged in the heterogeneous arrangement.

The drawers of the server node 1104 may be interchangeable, such that any of the drawers of the server node 1104 may be removed and replaced by a different drawer. The replacement drawer may have a same arrangement as the drawer removed or may have a different arrangement than the drawer that was removed. Accordingly, the server node 1104 may be transitioned among the pooled-by-node arrangement, the pooled-by-drawer arrangement, the heterogeneous arrangement, or some combination thereof via replacing the drawers of the server node 1104. Further, a malfunctioning drawer may be removed and replaced by a properly functioning drawer to limit downtime of the drawer and allow repair of the malfunctioning drawer without having to take the server node 1104 offline.

The server node 1106 may include one or more of the features of the server node 1104. The server node 1106 may have a same arrangement as the server node 1104 or may have a different arrangement than the server node 1104. For example, the server node 1104 may be arranged in a pooled-by-node arrangement and the server node 1106 may be arranged in a pooled-by-drawer arrangement.

As stated above, the resource types may include the network resource type, the storage resource type, and the compute resource type. The network resource type may include one or more components that may provide networking capability. The components included in the network resource type may include one or more I/O controllers (such as the I/O controller 1041 (FIG. 10)), one or more communication chips (such as the communication chips 1006 (FIG. 10)), one or more antennas (such as the antenna 1028 (FIG. 10)), or some combination thereof. In some embodiments, the components included in the network resource type may include other components that provide networking capability known to one having ordinary skill in the art.

The storage resource type may include one or more components that may provide storage capability. The components included in the storage resource type may include one or more memory controllers (such as the memory controller 1026 (FIG. 10)), one or more storage devices (such as the storage device 1054 (FIG. 10), one or more DRAMs (such as the DRAM 1020 (FIG. 10)), one or more flash memories (such as the flash memory 1022 (FIG. 10)), one or more ROMs (such as the ROM 1024 (FIG. 10), one or more volatile memory devices, one or more non-volatile memory devices, one or more mass storage devices (such as hard disk drives, solid state drives, compact disks (CDs), digital versatile disks (DVDs)), or some combination thereof. In some embodiments, the components included in the storage resource type may include other components that provide storage capability known to one having ordinary skill in the art.

The compute resource type may include one or more components that may provide computing capability. The components included in the compute resource type may include one or more processors (such as the processor 1004 (FIG. 10)), one or more graphics processors (such as the graphics processor 1030 (FIG. 10)), one or more digital signal processors, one or more crypto processors, one or more video codecs, one or more audio codecs, or some combination thereof. In some embodiments, the components included in the compute resource type may include other components that provide computing capability known to one having ordinary skill in the art.

In some embodiments, the resource types may include other resource types not described, but would be understood to be other resource types that may be provided by a server rack known to one have skill in the art. Further, in some embodiments, the resource types described may be divided into narrower resource types, where each of the narrower resource types may include some portion of the components described above in relation to the network resource type, the storage resource type, and the compute resource type.

After separating the operation 1108 into one or more discrete operations and/or data groupings for storage, the manager 1102 may direct each of the discrete operations and/or data groupings for storage to a corresponding drawer of the server node 1104 and/or the server node 1106 that provides the resource type to perform the discrete operation or store the data grouping. For example, the manager 1102 may separate the operation 1108 into a calculation operation and a group of data to be stored. The manager 1102 may direct, via the communication link 1118, the calculation operation to the drawer 1110 of the server node 1104, which may provide the compute resource type, and may direct, via the communication link 1120, the group of data to be stored to drawer 1122 of the server node 1106, which may provide the storage resource type.

After directing the discrete operations and/or the data groupings for storage to the corresponding drawers, the manager 1102 may retrieve the results of the discrete operations and/or the data groupings at a time when the results of the operation 1108 are to be returned to the requesting device via the communication chips. The manager 1102 may combine the results of the discrete operations and/or the data groupings to generate the results of the operation 1108 and may return the results of the operation 1108 to the requesting device via the communication chips.

In instances where the discrete operations are completed prior to the time when the results of the operation 1108 are to be returned to the requesting device, the manager 1102 may receive the results of the discrete operations and may direct the results of the discrete operations to a drawer providing the storage resource type for storage. The manager 1102 may then retrieve the results of the discrete operations from the drawer providing the storage resource type at the time when the results of the operation 1108 are to be returned to the requesting device.

In some embodiments, the manager 1102 may be omitted from the computing node arrangement 1100. In these embodiments, one or more drawers of one of the server nodes may perform the operations of the manager 1102. For example, the drawer 1110 of the server node 1104 may perform the operations of the manager 1102 and may direct the discrete operations and/or data groupings to other drawers within the server node 1104 and/or within the server node 1106. Further, in these embodiments, the server node with the drawer that performs the operations of the manager 1102 may be communicatively coupled to the other server nodes within the computing node arrangement 1100 (as illustrated by communication link 1124).

One or more of the computing nodes within the computing node arrangement 1100, and/or the drawers within the computing nodes, may include, and/or may be, a computer device (such as the computer device 1000 (FIG. 10)). Further, one or more of the computing nodes within the computing node arrangement 1100 and/or the drawers within the computing nodes may employ the apparatuses described herein (e.g., anti-recirculation device 100 (FIG. 1), the anti-recirculation device 510 (FIG. 5), and/or the anti-recirculation device 600 (FIG. 6)), in accordance with various embodiments. For example, the apparatuses described herein may be affixed to fans included in, or coupled to, one or more of the computing nodes within the computing node arrangement 1100.

Example 1 may include an apparatus for server computing, comprising a housing to be affixed adjacent to a fan associated with providing a flow of air to a compute, storage or network node, the housing being in line with the flow of air, and having an arrangement of apertures formed in a side of the housing, and a gate rotatably coupled to the housing, the gate including a door to rotate to cover the arrangement of apertures based on a lack of air being blown by the fan to prevent a back flow of air through the fan.

Example 2 may include the apparatus of example 1, wherein the door is to rotate away from the side of the housing and uncover the arrangement of apertures based on air being blown by the fan to allow the fan to provide the flow of air to the computer, storage or network node.

Example 3 may include the apparatus of examples 1 or 2, wherein the door includes a plurality of slats, and wherein the plurality of slats are to cover the arrangement of apertures based on the lack of air being blown by the fan to prevent the back flow of air through the fan.

Example 4 may include the apparatus of example 3, wherein each slat, of the plurality of slats, is tapered toward a side of the gate located away from the side of the housing.

Example 5 may include the apparatus of example 4, wherein the gate is at a certain angle to the side of the housing when the door is rotated away from the side of the housing, and wherein an amount of taper of each slat is based on the certain angle.

Example 6 may include the apparatus of example 3, wherein the plurality of slats extend in a horizontal direction.

Example 7 may include the apparatus of examples 1 or 2, wherein the arrangement of apertures extends for an entirety of the side of the housing.

Example 8 may include the apparatus of examples 1 or 2, wherein the arrangement of apertures is a grid of apertures.

Example 9 may include the apparatus of examples 1 or 2, wherein the gate includes a coupling member to couple the gate to the housing, and wherein the door is connected to the coupling member.

Example 10 may include the apparatus of example 9, wherein the coupling member forms a hinge with a portion of the housing.

Example 11 may include the apparatus of example 10, wherein the gate is to rotate about the portion of the housing.

Example 12 may include the apparatus of examples 1 or 2, wherein the gate is formed of plastic.

Example 13 may include the apparatus of examples 1 or 2, wherein the housing is affixed at an upstream side of the fan, and wherein the side of the housing is located opposite to the fan.

Example 14 may include the apparatus of examples 1 or 2, wherein the side of the housing is a first side of the housing, wherein a second side of the housing, the second side being opposite to the first side, abuts the fan, and wherein the second side has an aperture that extends for an entirety of the second side.

Example 15 may include the apparatus of examples 1 or 2, wherein a depth of the housing is less than three-quarters (1.905 cm) of an inch.

Example 16 may include a server computing node, comprising a case that houses components of the server computing node, a fan coupled to the case, the fan associated with providing a flow of air to the components, and an anti-recirculation device affixed adjacent to the fan, wherein the anti-recirculation apparatus includes a housing having an arrangement of apertures formed in a side of the housing, and a gate rotatably coupled to the housing, the gate including a door to rotate to cover the arrangement of apertures based on a lack of air being blown by the fan to prevent a back flow of air through the fan.

Example 17 may include the server computing node of example 16, wherein the door is to rotate away from the side of the housing and uncover the arrangement of apertures based on air being blown by the fan to allow the fan to provide the flow of air to the components.

Example 18 may include the server computing node of example 16, wherein the door includes a plurality of slats, and wherein the plurality of slats are to cover the arrangement of apertures based on the lack of air being blown by the fan to prevent the back flow of air through the fan.

Example 19 may include the server computing node of any of examples 16-18, wherein each slat, of the plurality of slats, is tapered toward a side of the gate located away from the side of the housing.

Example 20 may include the server computing node of example 19, wherein the gate as at a certain angle to the side of the housing when the door is rotated away from the side of the housing, and wherein an amount of taper of each slat is based on the certain angle.

Example 21 may include the server computing node of any of examples 16-18, wherein the plurality of slats extend in a horizontal direction.

Example 22 may include the server computing node of any of examples 16-18, wherein the gate further includes a coupling member that couples the gate to the housing, the door being connected to the coupling member.

Example 23 may include the server computing node of example 22, wherein the coupling member forms a hinge with a portion of the housing.

Example 24 may include the server computing node of example 23, wherein the gate is to rotate about the portion of the housing.

Example 25 may include the server computing node of any of examples 16-18, wherein the arrangement of apertures extends for an entirety of the side of the housing.

Example 26 may include the server computing node of any of examples 16-18, wherein the arrangement of apertures is a grid of apertures.

Example 27 may include the server computing node of any of examples 16-18, wherein the gate is formed of plastic.

Example 28 may include the server computing node of any of examples 16-18, wherein the anti-recirculation device is affixed at an upstream side of the fan, and wherein the side of the housing is located opposite to the fan.

Example 29 may include the server computing node of any of examples 16-18, wherein the side of the housing is a first side of the housing, wherein a second side of the housing, the second side being opposite to the first side, abuts the fan, and wherein the second side has an aperture that extends for an entirety of the second side.

Example 30 may include the server computing node of any of examples 16-18, wherein the anti-recirculation device has a depth of less than three-quarters of an inch.

Example 31 may include the server computing node of any of examples 16-18, wherein the components include at least one component selected from the group consisting of a processor, a memory device, a storage device, a memory controller, a communication chip, and an input/output controller.

Example 32 may include the server computing node of any of examples 16-18, wherein the server computing node is a selected one of a compute node, a storage node, or a network node of a server pod.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

What is claimed is:

1. An apparatus for server computing, comprising:
a housing to be affixed adjacent to a fan associated with providing a flow of air to a compute, storage or network node, the housing being in line with the flow of air, and having an arrangement of apertures formed in a side of the housing; and
a gate rotatably coupled to the housing, the gate including a door to rotate to cover the arrangement of apertures based on a lack of air being blown by the fan to prevent a back flow of air through the fan.

2. The apparatus of claim 1, wherein the door is to rotate away from the side of the housing and uncover the arrangement of apertures based on air being blown by the fan to allow the fan to provide the flow of air to the computer, storage or network node.

3. The apparatus of claim 1, wherein the door includes a plurality of slats, and wherein the plurality of slats are to cover the arrangement of apertures based on the lack of air being blown by the fan to prevent the back flow of air through the fan.

4. The apparatus of claim 3, wherein each slat, of the plurality of slats, is tapered toward a side of the gate located away from the side of the housing.

5. The apparatus of claim 4, wherein the gate is at a certain angle to the side of the housing when the door is rotated away from the side of the housing, and wherein an amount of taper of each slat is based on the certain angle.

6. The apparatus of claim 3, wherein the plurality of slats extend in a horizontal direction.

7. The apparatus of claim 1, wherein the arrangement of apertures extends for an entirety of the side of the housing.

8. The apparatus of claim 1, wherein the arrangement of apertures is a grid of apertures.

9. The apparatus of claim 1, wherein the gate includes a coupling member to couple the gate to the housing, and wherein the door is connected to the coupling member.

10. The apparatus of claim 9, wherein the coupling member forms a hinge with a portion of the housing.

11. The apparatus of claim 10, wherein the gate is to rotate about the portion of the housing.

12. The apparatus of claim 1, wherein the gate is formed of plastic.

13. The apparatus of claim 1, wherein the housing is affixed at an upstream side of the fan, and wherein the side of the housing is located opposite to the fan.

14. A server computing node, comprising:
a case that houses components of the server computing node;
a fan coupled to the case, the fan associated with providing a flow of air to the components; and
an anti-recirculation device affixed adjacent to the fan, wherein the anti-recirculation apparatus includes:
a housing having an arrangement of apertures formed in a side of the housing; and
a gate rotatably coupled to the housing, the gate including a door to rotate to cover the arrangement of apertures based on a lack of air being blown by the fan to prevent a back flow of air through the fan.

15. The server computing node of claim 14, wherein the door is to rotate away from the side of the housing and uncover the arrangement of apertures based on air being blown by the fan to allow the fan to provide the flow of air to the components.

16. The server computing node of claim 14, wherein the door includes a plurality of slats, and wherein the plurality of slats are to cover the arrangement of apertures based on the lack of air being blown by the fan to prevent the back flow of air through the fan.

17. The server computing node of claim 14, wherein each slat, of the plurality of slats, is tapered toward a side of the gate located away from the side of the housing.

18. The server computing node of claim 17, wherein the gate as at a certain angle to the side of the housing when the door is rotated away from the side of the housing, and wherein an amount of taper of each slat is based on the certain angle.

19. The server computing node of claim 14, wherein the plurality of slats extend in a horizontal direction.

20. The server computing node of claim 14, wherein the gate further includes a coupling member that couples the gate to the housing, the door being connected to the coupling member.
